(19) United States
(12) Patent Application Publication
(10) Pub. No.: US 2015/0318446 A1
(43) Pub. Date: Nov. 5, 2015

(54) Low-Temperature Fabrication of Transparent Conductive Contacts for p-GaN and n-GaN

(71) Applicant: Intermolecular, Inc., San Jose, CA (US)

(72) Inventors: Jianhua Hu, Palo Alto, CA (US); Heng Kai Hsu, Hisnchu (TW); Minh Huu Le, San Jose, CA (US); Sandeep Nijhawan, Los Altos, CA (US); Teresa B. Sapirman, Mountain View, CA (US)

(73) Assignee: Intermolecular, Inc., San Jose, CA (US)

(21) Appl. No.: 14/265,763

(22) Filed: Apr. 30, 2014

(51) Int. Cl. H01L 33/42; H01L 33/46; H01L 33/00; H01L 33/32

(52) U.S. Cl. CPC H01L 33/42; H01L 33/32; H01L 33/46; H01L 33/005; H01L 2933/0016

(57) ABSTRACT

A ternary transparent conductive oxide, indium zinc oxide (IZO), is formed as a thin film by co-sputtering zinc oxide with indium oxide at a deposition temperature between 25 and 200 C. Optionally, up to 1-2% Al may be added by various methods. The layers may be annealed at temperatures between 200 and 400 C. Measurements of IZO with 75-85 wt % In₂O₃ showed low resistivity and low visible absorbance, both of which were thermally stable up to 400 C.

### BACKGROUND

Related fields include light-emitting diodes (LEDs) and other optoelectronic devices based on III-V materials, transparent conductive films for optoelectronic devices, and physical vapor deposition (PVD), particularly sputtering.

A typical LED emits light from an active photoemissive semiconductor layer sandwiched between p-type and n-type semiconductor layers. Electroluminescence results when negative charge carriers (electrons) from the n-type layer and positive charge carriers (“holes”) from the p-type layer meet and combine in the active photoemissive layer.

The wavelength and color of the emitted light depends, at least in part, on the semiconductor bandgap. For example, arsenides of aluminum(AI), gallium (Ga), indium (In), and their alloys emit red and infrared light; phosphides of Al, Ga, In, and their alloys emit green, yellow, or red light; and nitrides of Al, Ga, In, and their alloys emit ultraviolet, violet, blue, or green light. These “III-V materials,” so-called because they include elements from old group III (now group 13) and old group V (now group 15) of the periodic table, have high carrier mobility and direct bandgaps that are desirable in optoelectronic applications. However, substrates made of III-V materials have historically been very expensive. GaN and AIN substrates are becoming increasingly available, but problems with instability and defects persist. A common alternative approach has been to grow III-V layers by epitaxy on a different substrate material such as sapphire (Al2O3), silicon (Si), silicon carbide (SiC), germanium (Ge), zinc oxide (ZnO), and glass.

A “junction-up” LED emits its output light in a direction pointing away from the substrate, while an inverted, or “flip-chip,” LED emits its output light toward the substrate. Both types may use transparent electrodes on the light-emitting side to facilitate the passage of both electrical current and light through the semiconductor stack. Other devices with similar requirements for current and light traversing the same surface also use transparent electrodes. Many thin-film materials for transparent electrodes are oxides, and are generically known as “transparent conductive oxides” (TCO).

Indium tin oxide, (ITO), the most common TCO material for transparent electrodes, is expensive because it is typically over 90% indium. The optical transparency and the conductivity generally need to be traded off against each other because the highest-transparency formulations are generally different from the highest-conductivity formulations. In addition, both the optical transparency and the conductivity may be unstable with temperature, and therefore may change unpredictably during high-temperature process steps, such as annealing, that may be required to fabricate either the TCO itself or other parts of the device.

Therefore, a need exists for a cost-effective TCO material with transmissivity and conductivity that are stable throughout the temperature range of fabrication processes for LEDs and other optoelectronic devices. Preferably, the TCO material should be tunable to optimize for lowest resistivity or lowest optical absorption, as required by the device being fabricated.

### SUMMARY

The following summary presents some concepts in a simplified form as an introduction to the detailed description that follows. It does not necessarily identify key or critical elements and is not intended to reflect a scope of invention.

Embodiments of transparent conductive contacts include ternary indium zinc oxide (IZO). Some embodiments of the IZO contacts include up to 2% aluminum (Al). The thickness of the IZO transparent conductive layers may be between about 20 nm and 200 nm. The composition of the IZO may be tuned to optimize the TCO's resistivity and absorption coefficient.

In some embodiments, the In content of the IZO transparent conductive layers is between about 60% and 92% indium oxide by weight. For example, the IZO transparent conductive layer may include between about 80 wt % and 85 wt % In₂O₃, less than the 90 wt % indium oxide typical of ITO. Lowest resistivity formulations may have 80-90 wt % indium oxide, and highest transparency formulations may have 60-80 wt % indium oxide. In some embodiments, the concentration of conductive phase Zn₂In₂O₅is increased to raise the conductivity of the layer or decreased to reduce the absorbance (and raise the transmissivity) of the layer. Oxygen may be minimized or excluded from the process gas to reduce both resistivity and absorption. In some embodiments, the IZO transparent conductive layers have a sheet resistivity less than 300 μΩ-cm and an optical absorbance of about 0.01-0.02%/nm for visible light. The resistivity and absorbance is stable after annealing at 200-550 C.

Some embodiments of methods for fabricating IZO conductive layers include co-sputtering from a zinc oxide (ZnO) target and an indium oxide (In₂O₃) target. The sputter power density may be between about 2.5 and 20 W/cm² (e.g., 50-400 W on a 5-cm diameter target). Optionally, Al may be added by using a 98-99% aluminum zinc oxide (AZO) target, by sputtering Al from a separate target, or by other doping methods such as ion implantation or thermal diffusion. In some embodiments, the deposition temperature may be between about 25 C and 200 C. The deposition may include injecting a gaseous oxygen source into the chamber, or it may not. In some embodiments, the deposition may be followed by annealing at a temperature between about 200 C and 550 C (e.g., 300 C). In some embodiments, the absorbance may be further reduced by annealing at a temperature above 300 C.

Some embodiments of LEDs include an active photoemissive layer between a p-type semiconductor layer and an n-type semiconductor layer, and an AZO transparent conductive layer over either the p-type semiconductor or the n-type semiconductor layer.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIGS. 1A and 1B conceptually illustrate examples of LEDs.

FIGS. 2A and 2B conceptually illustrate some alternative placements of TCO layers in junction-up and flip-chip LEDs.

FIG. 3 is a block diagram of an example of a PVD chamber configured for co-sputtering.

FIGS. 4A and 4B are example graphs of resistivity and absorption coefficient (for ˜460 nm light) of IZO layers as a function of wt % indium oxide.

FIGS. 5A and 5B are example graphs of resistivity and absorption coefficient of IZO layers as a function of % oxygen in the process gas used during deposition.

FIG. 6 is an example graph of absorption as a function of wavelength for 200 nm-thick annealed IZO layers of different compositions.

FIG. 7 is a flowchart of an example process for fabricating an optoelectronic device using p-GaN or n-GaN and an IZO transparent conductive layer.

FIG. 8 is a process flowchart for forming an IZO transparent conductive layer.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) By default, singular articles “a,” “an,” and “the” (or the absence of an article) may encompass plural variations; for example, “a layer” may mean “one or more layers.” (2) “Or” in a list of multiple items means that any, all, or any combination of less than all the items in the list may be used in the invention. (3) Where a range of values is provided, each intervening value is encompassed within the invention. (4) “About” or “approximately” contemplates up to 10% variation. “Substantially equal,” “substantially unchanged” and the like contemplate up to 5% variation.

“Horizontal” defines a plane parallel to the plane or surface of the substrate. “Vertical” shall mean a direction perpendicular to the horizontal. “Above,” “below,” “bottom,” “top,” “side” (e.g. sidewall), “higher,” “lower,” “upper,” “over,” and “under” are defined with respect to the horizontal plane. “On” indicates direct contact; “above” and “over” allow for intervening elements. “On” and “over” include conformal configurations covering feature walls oriented in any direction.

“Substrate,” as used herein, may mean any workpiece on which formation or treatment of material layers is desired. Substrates may include, without limitation, silicon, germanium, silica, sapphire, zinc oxide, SiC, AIN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein. Semiconductor wafer shapes and sizes can vary and include commonly used round wafers of 50 mm, 100 mm, 150 mm, 200 mm, 300 mm, or 450 mm in diameter. Furthermore, the substrates may be processed in many configurations such as single substrate processing, multiple substrate batch processing, in-line continuous processing, in-line “stop and soak” processing, or roll-to-roll processing.

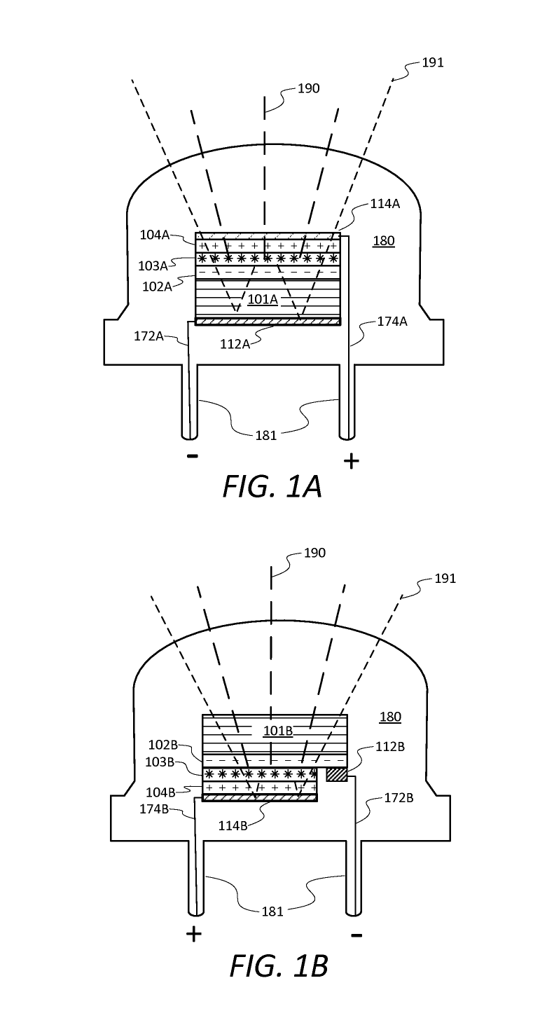

FIGS. 1A and 1B conceptually illustrate examples of LEDs. Many different LED designs exist, and new ones continue to be introduced. These examples are intended to provide basic context and do not limit the scope of application of the described components and methods.

FIG. 1A illustrates an example of a junction-up LED. A “junction-up” LED emits light from the side opposite the substrate, through a transparent or semi-transparent electrode. Inside the transparent envelope of package 180, substrate 101A supports n-type semiconductor layer 102A, active photoemissive layer 103 A, and p-type semiconductor layer 104A. Collectively, the n-type, photoemissive, and p-type layers, along with any intervening layers between them, may be referred to as the “active stack.” Current delivered through terminal pins 181 is conducted through leads 172A and 174A to negative electrode 112A and positive electrode 114A. Some junction-up LEDs have one electrode on the “top” (the side of the film stack farthest from the substrate) and one on the “bottom” (the side of the film stack nearest the substrate). The current causes negative charge-carriers to migrate from n-type layer 102A into active photoemissive layer 103A, and positive charge-carriers to migrate from p-type layer 104A into active photoemissive layer 103A. When the negative charge-carriers and positive charge-carriers recombine in active photoemissive layer 103A, photons of light are emitted.

Upward-directed light 190 passes through positive-polarity contact 114A, illustrated here as a transparent electrode. In some LEDs, positive-polarity contact 114A is opaque or reflecting, but only covers part of the top surface so that light may emerge from the uncovered parts of the surface. Downward-directed light 191 passes through substrate 101A and is reflected from reflective negative-polarity contact 112A to redirect it upward, where it exits from the top surface.

In some junction-up LEDs, reflective negative-polarity contact 112A is between substrate 101A and n-type layer 102A. These designs do not require substrate 101A to be transparent; it may be an opaque material such as silicon carbide. In some junction-up LEDs, the positive-polarity components are underneath the active photoemissive layer and the negative-polarity components are above it.

FIG. 1B illustrates an example of a flip-chip LED. A flip-chip LED is fabricated to emit its output light toward the substrate. Originally, the film stack is formed on substrate 101B, but when the die is installed in package 180, it is inverted or “flipped” upside-down to position substrate 101B on top. Thus “substrate” 101B becomes a “superstrate.” In the illustrated example, superstrate 101B remains as part of the finished device, and therefore preferably transmits the emitted wavelength(s). In some embodiments, superstrate 101B is removed from the finished device, so its transparency is not a constraint. In the illustrated example, part of the surface of n-type semiconductor layer 102B is exposed to allow the attachment of negative-polarity contact 112B, which makes contact only with part of the n-type layer. In some LEDs, this removes or relaxes the requirement that negative-polarity contact 112B have any particular optical properties such as transparency.

When current passes through the device from pins 181 through leads 172B and 174B, light is emitted from active photoemissive layer 103B. Light emitted from active photoemissive layer 103B toward superstrate 101B is transmitted directly out of the device. Light emitted from active photoemissive layer 103B toward p-type layer 104B is reflected from reflective positive-polarity contact 114B, which redirects it upward through superstrate 101B.

Transparent conductive oxide (TCO) materials are used, for example, as top (positive-polarity) electrode 114A in FIG. 1A, forming a contact to p-doped layer 104A. Some embodiments of junction-up LEDs may alternatively reverse the positions of p-type layer 104A and n-type layer 102A, so that top electrode 114A forms a contact to n-type layer 102A instead.

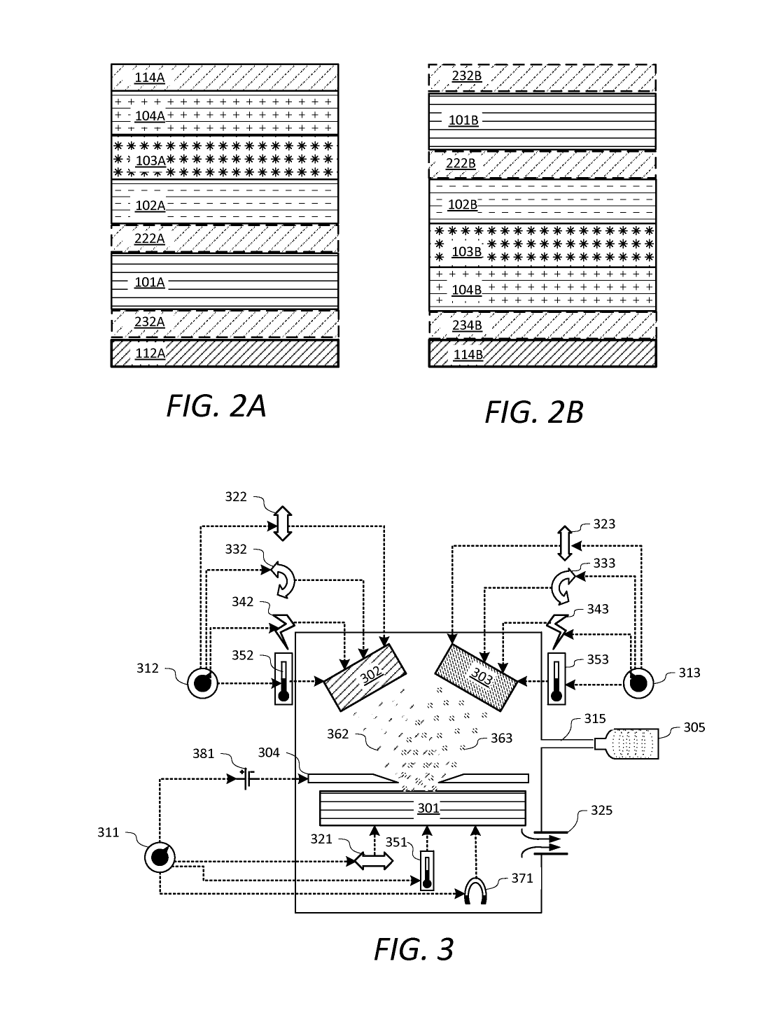

FIGS. 2A and 2B conceptually illustrate some alternative placements of TCO layers in junction-up and flip-chip LEDs. Besides being used as top electrodes in junction-up LEDs (p-contact 114A in FIG. 2A), TCO layers 222A or 222B may be used between the active stack and the substrate. TCO layers may form part of a compound electrode stack with a reflective electrode: TCO layer 232A with reflective layer 112A or TCO layer 234B with reflective layer 114B. In some flip-chip embodiments, a TCO layer may also be used over substrate 101B. These TCO layers may be used as intermediate electrodes, as alternatives to the small-area electrode 112B in FIG. 1B, or, since many TCO materials block diffusion of metals and other reactive materials, as diffusion barriers. The IZO and Al:IZO materials described herein may be used anywhere a similar TCO, such as ITO, would be used.

FIG. 3 is a block diagram of an example of a PVD chamber configured for co-sputtering. Substrate 301 receives a first sputtered material 362 from a first target 302 and a second sputtered material 363 from a second target 303. A controller 312 may control one or more of position 322, angle 332, plasma power 342, and temperature 352 of target 302. A controller 313 may control one or more of position 323, angle 333, plasma power 343, and temperature 353 of target 303. Although the illustrated system shows two targets for simplicity, some embodiments may use more than two targets.

Controllers 312 and 313 for the separate targets may independently vary the respective targets' position, angle, or plasma power as sputtering continues. Thus the separate targets can be sputtered at different plasma power levels, or from different throw distances to the substrate, to vary the relative concentrations of each target material being deposited on the substrate. If at least one of the variables can be changed while sputtering continues, the composition of the film may be varied with depth if desired. Process gases from one or more gas sources 305 may be injected into the chamber through gas inlet(s) 315, and removed from the chamber, along with process by-products, through one or more vacuum exhaust ports 325.

Some process chambers also have a controller 311 to vary the position 321, temperature 351, and local magnetic field 371 of substrate 301. Like the other controllers 312 and 313, controller 311 may be programmable, may be remote from the process chamber and operate via a wireless connection, and may be capable of varying the substrate's position, angle, plasma power, or temperature in real time as sputtering continues. “Position” in this block diagram is symbolized by a single two-headed arrow for simplicity, but it is intended to symbolize position variation in any or all directions. Some process chambers also have a mask 304 to block sputtered materials 362, 363 from reaching selected parts of substrate 301. Optionally, a controllable bias voltage 381 may be applied to mask 304. In process chambers equipped to change the relative position of substrate 301 and mask 304 during processing, different parts of substrate 301 may be sputtered with material having different proportions of first material 362 and second material 363.

By co-sputtering from separate targets made from ZnO and In₂O₃, the relative weight percentages of the two components can be controlled by controlling the power applied to each target. Alternatively, the sputtering distance or angle of each sputter gun relative to the substrate may be varied.

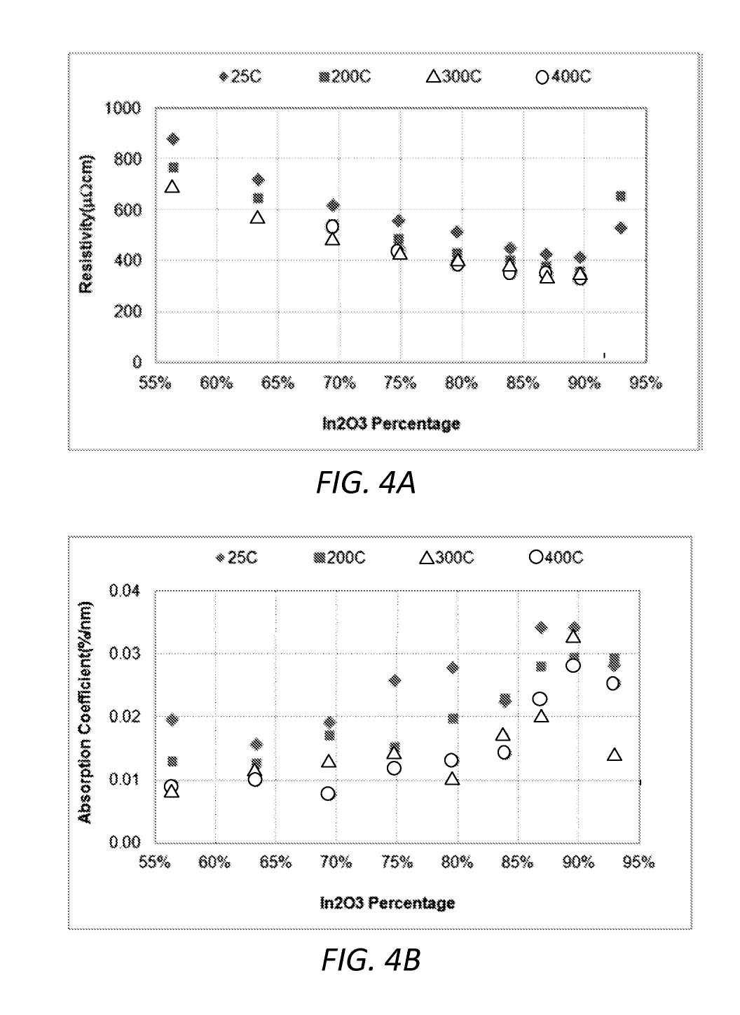

FIGS. 4A and 4B are example graphs of resistivity and absorption coefficient (for ˜460 nm light) of IZO layers as a function of wt % indium oxide. In these experiments, the deposition temperature was about 150 C with a chamber pressure of about 2 mTorr. 300 W of plasma power was divided between the two 2″ targets (i.e., 300 W on one target and 0 on the other for pure ZnO and In₂O₃, 150 W on each target for ZnO:In₂O₃=1:1 by weight, etc.)The relative wt % of ZnO and In₂O₃ was controlled by adjusting the power at the separate targets. The data point shapes correspond to the post-deposition anneal temperatures: diamond for 25C, square for 200 C, triangle for 300 C, and circle for 400 C. Anneal times were about 5 minutes. Anneal temperatures of 300 and 400 C produced the lowest resistivity and the lowest absorbance. Resistivity was lowest between 80-90 wt % In₂O₃, but absorbance was lowest below 85 wt % In₂O₃. One value with low resistivity and low absorbance was about 83 wt % In₂O₃. X-ray diffraction (XRD) measurements showed a strong peak for conductive Zn₂In₂O₅ at 83 wt % In₂O₃, which was absent at both higher (92-100 wt %) and lower (0-71 wt %) In₂O₃.

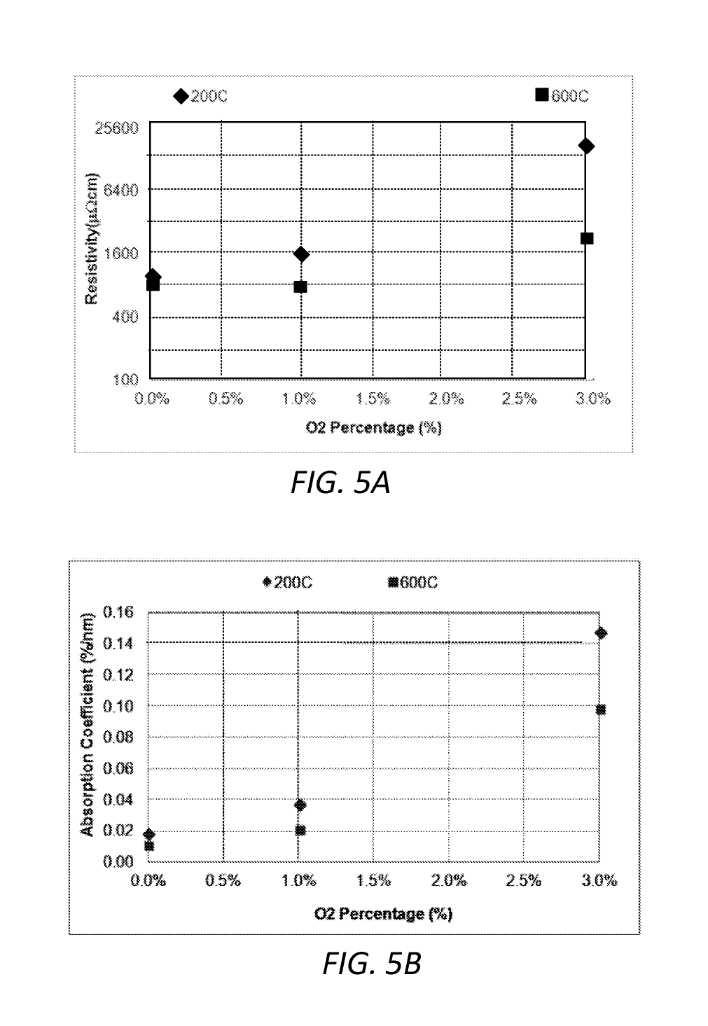

FIGS. 5A and 5B are example graphs of resistivity and absorption coefficient of IZO layers as a function of % oxygen in the process gas used during deposition. More specifically, the % O₂ refers to oxygen gas intentionally added to the PVD chamber from an external gas source such as gas source 305 in FIG. 3, as distinct from oxygen or oxygen-containing gases that may be in the chamber as by-products of sputtering the oxide target, or from other sources. Depositions with no O₂ in the process gas were compared to depositions with 1-3% O₂ in the process gas. In all cases, both resistivity and absorbance increased by at least a factor of 1.5-2.5 for every 1% of O₂ in the process gas, and were lowest when no O₂ was added to the process gas.

Additionally, experiments showed that resistivity and absorbance were nearly independent of target power density from about 200-400 W on a 2″ target (˜10-20 W/cm²). However, the XRD peak for <0 0 2> ZnO was strongest (indicating the comparatively highest degree of crystallinity) at the high end of the power range. Therefore, in some embodiments, a power density of 17-20 W/cm² produces a more crystalline TCO without compromising resistivity or absorbance.

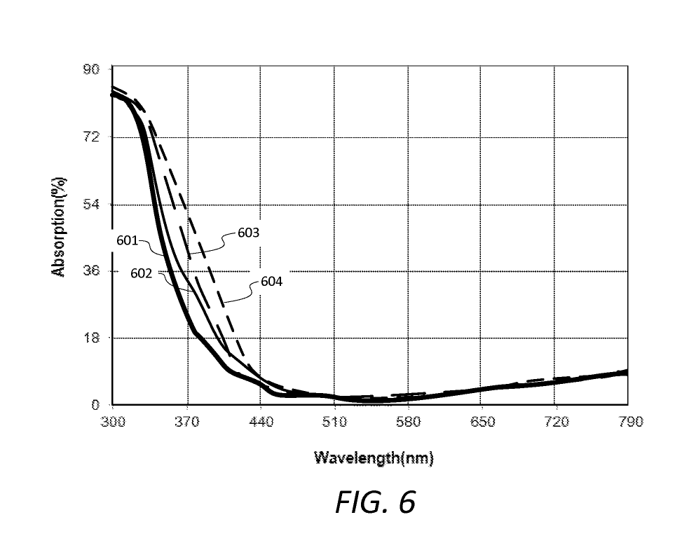

FIG. 6 is an example graph of absorption as a function of wavelength for 200 nm-thick annealed IZO layers of different compositions. Curve 601 represents a result for 100 wt % In₂O₃ as a reference. Curve 602 represents IZO with 93 wt % In₂O₃. Curve 603 represents IZO with 71-83 wt % In₂O₃(results were too close to be resolved at this scale). Curve 604 represents IZO with 55 wt % In₂O₃. For wavelengths between about 440-790 nm (blue-green, green, yellow, orange, red and near infrared) the absorption is independent of the wt % ratio of In₂O₃ and ZnO. For 350-440 nm (blue, indigo, violet, and near ultraviolet) the absorption is lower for compositions with less ZnO.

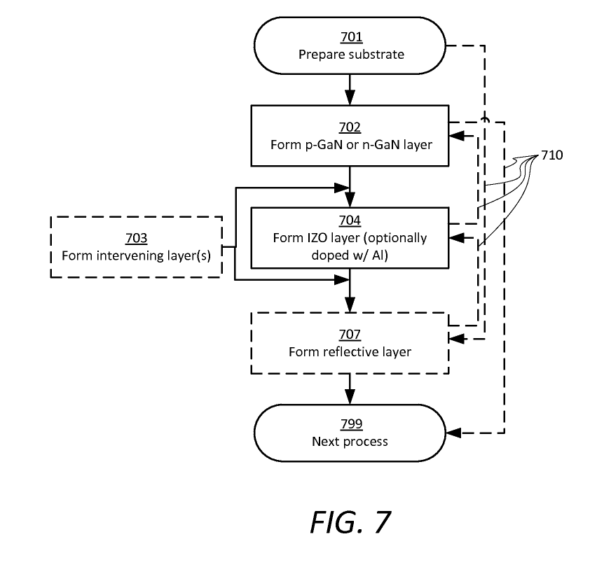

FIG. 7 is a flowchart of an example process for fabricating an optoelectronic device using p-GaN or n-GaN and an IZO transparent conductive layer. Step 701 of preparing a substrate may include cleaning, degassing, or forming one or more layers or structures. Step 702 of forming a p-GaN or n-GaN layer may include doping a GaN substrate, or alternatively may include any method of forming such a layer on a non-GaN substrate including epitaxy, atomic layer deposition (ALD), chemical vapor deposition (CVD), or plasma-enhanced variations.

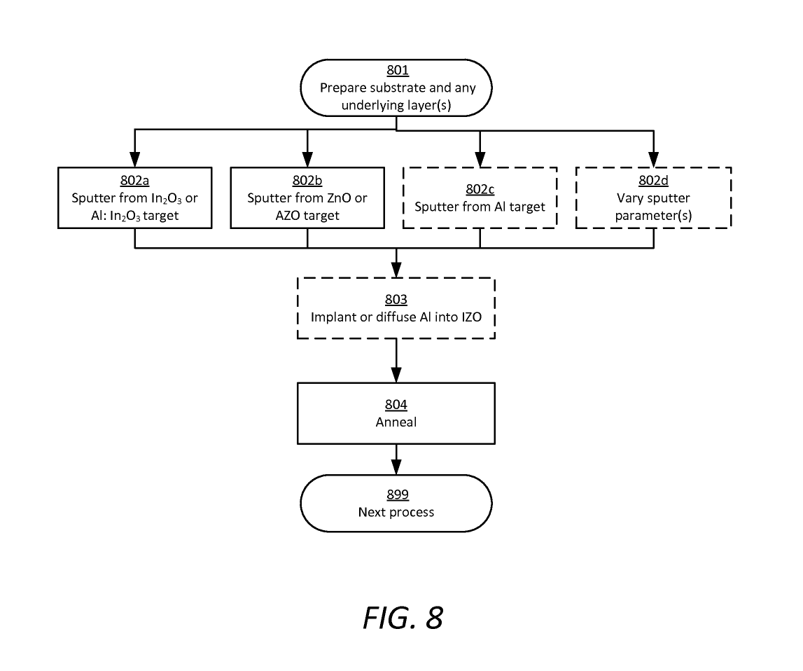

Step 704 of forming the IZO layer may directly follow p-GaN or n-GaN formation 702 so that the IZO directly contacts the p-GaN or n-GaN. Alternatively, optional step 703 of forming one or more intervening layers may be done between step 702 and step 704. Details and options for step 704 are described with reference to FIG. 8.

Optional step 707 of forming a reflective layer may directly follow IZO formation step 704, or one or more intervening layer formations 703 may be done between steps 704 and 707. The reflective layer is added if the optoelectronic device requires it; for example, in a flip-chip LED, the reflective layer may be formed over the IZO. After the reflective layer formation 707, the next process 799 may commence.

Dashed arrows 710 represent an alternate process order, wherein the optional reflective layer may be formed before and below the IZO layer, and the p-GaN or n-GaN layer may be formed after and above the IZO layer. In that process order, the substrate is prepared in step 701; then the reflective layer, if used, is formed in step 707; then optional intervening layers may be formed in step 703; the IZO layer is formed in step 704; then other optional intervening layers may be formed in step 703; then the p-GaN or n-GaN layer is formed in step 702; then the next process 799 may commence.

FIG. 8 is a process flowchart for forming an IZO transparent conductive layer. For example, these processes may be used in step 704 of FIG. 7. Step 801 of preparing the substrate and any underlying layer(s) may include, for example, cleaning and degassing the substrate, forming a p-GaN or n-GaN layer, forming a reflective layer, or forming any other appropriate layers or structures. Deposition of the IZO includes step 802a of sputtering indium oxide and step 802b of sputtering zinc oxide, and may optionally also include step 802c of sputtering Al and/or step 802d of varying the sputter parameters.

For example, in optional step 802d the sputter power, the throw-distance from the target to the substrate, the angle of the target relative to the substrate, and other parameters may be varied to manipulate the relative amounts of zinc oxide and indium oxide in the layer being formed. In some embodiments, one of these parameters may be varied during the deposition to produce a composition gradient in the IZO layer. In some embodiments, the wt % of In₂O₃ may be between about 80% and 90% to minimize resistivity. In some embodiments, the wt % of In₂O₃ may be between about 60% and 80% to minimize absorbance of visible light. In some embodiments, the wt % of In₂O₃ may be between about 75% and 85% to produce an optimal trade-off between resistivity and absorbance.

Steps 802a-802d of depositing the IZO may be simultaneous, partially simultaneous (i.e. simultaneous for some time although one of the steps may begin before, or end after, another), sequential, or alternating. For example, some sputtering 802a-b may occur, then a parameter change 802d, then more sputtering 802a-b with the changed parameter; alternatively, the parameter change 802d may be done while sputtering continues. As another example, In₂O₃ sputtering 802a may alternate with ZnO sputtering 802b to form a nanolaminate.

The deposition temperature may be between about 25 C and 200 C. The sputter power density may be between about 2.5 and 20 W/cm² (e.g., 50-400 W on a 5-cm diameter target). The deposition may include injecting an oxygen-containing gas (e.g., O₂, O₃, H₂O, NO₂) into the chamber, or it may exclude injecting oxygen-containing gases (e.g., only non-oxygen-containing gases such as Ar may be injected) to decrease resistivity and absorbance.

In some embodiments, the IZO layer may include up to 2% Al. The Al may be added by sputtering the zinc oxide from a 98-99% aluminum zinc oxide (AZO) target, a 98-99% aluminum-doped indium oxide target, or in optional step 802c from a separate aluminum target. In optional step 803, Al may be added to the IZO layer by ion implantation. As another alternative, a thin layer of Al may be sputtered from an Al target in step 802c and thermally diffused into the IZO, e.g., by annealing step 804.

In step 804 of annealing, the substrate may be heated to a temperature between about 200 C and 400 C (e.g., 300 C) for about 1-10 minutes (e.g., 5 minutes). In some embodiments, the absorbance may be further reduced by annealing at a temperature above 300 C. The annealing may be done at any point after deposition of the IZO; directly after deposition, or after subsequent processes such as the formation of other layers or structures.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. An optoelectronic device, comprising:
a substrate;
a gallium nitride (GaN) layer formed over or in the substrate; and
a transparent conductive layer formed over the GaN layer;
wherein the transparent conductive layer comprises indium zinc oxide;
wherein the indium zinc oxide comprises indium oxide; and
wherein a weight percentage of the indium oxide in the indium zinc oxide is between about 60% and about 92%.

2. The device of claim 1, wherein the indium zinc oxide further comprises a weight percentage of aluminum between about 0% and about 2%.

3. The device of claim 1, wherein the transparent conductive layer directly contacts the GaN layer.

4. The device of claim 1, wherein the transparent conductive layer comprises <0 0 2> crystalline ZnO.

5. The device of claim 1, wherein the GaN layer is p-doped.

6. The device of claim 1, wherein a thickness of the transparent conductive layer is between about 20 nm and 200 nm.

7. The device of claim 1, wherein the GaN layer is formed over the substrate.

8. The device of claim 1, wherein the weight percentage of the indium oxide is between about 80% and about 90%.

9. The device of claim 1, wherein the weight percentage of the indium oxide is between about 60% and about 80%.

10. The device of claim 1, wherein the weight percentage of the indium oxide is between about 75% and about 85%.

11. The device of claim 7, further comprising:
a reflective layer formed on a side of the substrate opposite the GaN layer and the transparent conductive layer;
a first lead, the first lead being electrically connected to transparent conductive layer; and
a second lead, the second lead being electrically connected to the reflective layer.

12-20. (canceled)

21. An optoelectronic device, comprising:
a substrate;
a first gallium nitride (GaN) layer formed over or in the substrate;
an active photoemissive layer formed over the first GaN layer;
a second GaN layer formed over the active photoemissive layer; and
a transparent conductive layer formed over the second GaN layer, wherein the transparent conductive layer comprises indium zinc oxide, the indium zinc oxide comprises indium oxide, and a weight percentage of the indium oxide in the indium zinc oxide is between about 60% and about 92%.

22. The device of claim 21, wherein the first GaN layer is formed over the substrate.

23. The device of claim 22, further comprising a second transparent conductive layer formed between the substrate and the first GaN layer.

24. The device of claim 23, wherein the second transparent conductive layer comprises indium zinc oxide, wherein the indium zinc oxide of the second transparent conductive layer comprises indium oxide.

25. The device of claim 24, wherein a weight percentage of the indium oxide in the indium zinc oxide of the second transparent conductive layer is between about 60% and about 92%.

26. The device of claim 25, wherein the second transparent conductive layer is formed directly on the substrate, and the first GaN layer is formed directly on the second transparent conductive layer.

27. The device of claim 21, further comprising:
a reflective layer formed on a side of the substrate opposite the active photoemissive layer and the second GaN layer;
a first lead, the first lead being electrically connected to transparent conductive layer; and
a second lead, the second lead being electrically connected to the reflective layer.
